(19) United States
(12) Patent Application Publication
(10) Pub. No.: US 2024/0088055 A1
(43) Pub. Date: Mar. 14, 2024

(54) SEMICONDUCTOR PACKAGE INCLUDING ALIGNMENT MARKS

(71) Applicant: SAMSUNG ELECTRONICS CO., LTD., Suwon-si (KR)

(72) Inventors: Inhyung SONG, Suwon-si (KR); Jaegwon Jang, Suwon-si (KR); Yeonho Jang, Suwon-si (KR)

(73) Assignee: SAMSUNG ELECTRONICS CO., LTD., Suwon-si (KR)

(21) Appl. No.: 18/368,309

(22) Filed: Sep. 14, 2023

(30) Foreign Application Priority Data
Sep. 14, 2022 (KR) 10-2022-0115804

(51) Int. Cl. H01L 23/544; H01L 23/00; H01L 23/31; H01L 23/498; H01L 25/10

(52) U.S. Cl. CPC H01L 23/544; H01L 23/3128; H01L 23/49811; H01L 23/49822; H01L 24/20; H01L 25/105; H01L 24/16; H01L 2223/54426; H01L 2224/16227; H01L 2224/21

(57) ABSTRACT

A semiconductor package includes a base structure having a fan-in area and fan-out areas surrounding the fan-in area, a semiconductor chip in the fan-in area, a package body layer in the fan-in area and the fan-out areas and covering the semiconductor chip, a redistribution structure on the package body layer, and alignment marks on the redistribution structure in a plan view. Each of the alignment marks includes a plurality of metal layers, and a plurality of auxiliary patterns are in the redistribution structure under the alignment marks to assist in recognition of the alignment marks.

### CROSS-REFERENCE TO RELATED APPLICATION

This application is based on and claims priority under 35 U.S.C. § 119 to Korean Patent Application No. 10-2022-0115804, filed on Sep. 14, 2022, in the Korean Intellectual Property Office, the disclosure of which is incorporated by reference herein in its entirety.

### BACKGROUND

The disclosure relates to a semiconductor package, and more particularly, to a fan-out semiconductor package.

In accordance with the rapid development of the electronics industry and user demand, semiconductor packages as key components of electronic devices are required to have high performance and to be multifunctional. In order to meet such requirements, a fan-out semiconductor package has been suggested. When the fan-out semiconductor package includes a lower semiconductor package and an upper semiconductor package with a function different from that of the lower semiconductor package that is stacked on the lower semiconductor package, high performance and multifunctionality may be achieved.

### SUMMARY

The disclosure relates to a semiconductor package including a redistribution structure on which an upper semiconductor package is easily stacked.

In accordance with an aspect of the disclosure, a semiconductor package includes a base structure having a fan-in area and fan-out areas surrounding the fan-in area; a semiconductor chip in the fan-in area; a package body layer in the fan-in area and the fan-out areas, the package body layer covering the semiconductor chip; a redistribution structure on the package body layer; and alignment marks on the redistribution structure in a plan view, wherein each of the alignment marks includes a plurality of metal layers, and wherein a plurality of auxiliary patterns are in the redistribution structure under the alignment marks to assist in recognition of the alignment marks.

In accordance with an aspect of the disclosure, a semiconductor package includes a lower redistribution structure having a fan-in area and fan-out areas surrounding the fan-in area; a semiconductor chip in the fan-in area; a package molding layer in the fan-in area and the fan-out areas, the package molding layer covering the semiconductor chip; an upper redistribution structure on the package molding layer; a metal post layer in the package molding layer, the metal post layer electrically connecting the lower redistribution structure to the upper redistribution structure; and alignment marks on the upper redistribution structure in a plan view, wherein each of the alignment marks includes a plurality of metal layers, and wherein a plurality of auxiliary patterns are in the upper redistribution structure under the alignment marks to assist in recognition of the alignment marks.

In accordance with an aspect of the disclosure, a semiconductor package includes a lower semiconductor package; an upper semiconductor package stacked on the lower semiconductor package, the upper semiconductor package having a size less than a size of the lower semiconductor package; and a plurality of package connection terminals electrically connecting the lower semiconductor package to the upper semiconductor package, wherein the lower semiconductor package includes a lower redistribution structure having a fan-in area and fan-out areas surrounding the fan-in area; a semiconductor chip in the fan-in area; a package molding layer in the fan-in area and the fan-out areas, the package molding layer covering the semiconductor chip; an upper redistribution structure on the package molding layer; a metal post layer in the package molding layer, the metal post layer electrically connecting the lower redistribution structure to the upper redistribution structure; and alignment marks on the upper redistribution structure in a plan view, wherein each of the alignment marks includes a plurality of metal layers, and wherein a plurality of auxiliary patterns are in the upper redistribution structure under the alignment marks to assist in recognition of the alignment marks.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a cross-sectional view of a semiconductor package according to an embodiment;

FIG. 2 is a schematic top plan view of the semiconductor package of FIG. 1;

FIGS. 3 and 4 are plan views each illustrating an alignment mark and a plurality of auxiliary patterns of the semiconductor package of FIGS. 1 and 2;

FIG. 5 is an enlarged plan view illustrating a plurality of auxiliary patterns of the semiconductor package of FIGS. 1 and 2;

FIG. 6 is an enlarged cross-sectional view illustrating an enlarged part of the semiconductor package of FIG. 1 according to an embodiment;

FIG. 7 is an enlarged cross-sectional view illustrating an alignment mark and a plurality of auxiliary patterns of the semiconductor package of FIG. 1 according to an embodiment;

FIG. 8 is an enlarged cross-sectional view illustrating an enlarged part of a semiconductor package according to an embodiment;

FIG. 9 is an enlarged cross-sectional view illustrating an alignment mark and a plurality of auxiliary patterns of the semiconductor package according to an embodiment;

FIG. 10 is an enlarged cross-sectional view illustrating an enlarged part of a semiconductor package according to an embodiment;

FIG. 11 is an enlarged cross-sectional view illustrating an alignment mark and a plurality of auxiliary patterns of the semiconductor package according to an embodiment;

FIG. 12 is a cross-sectional view illustrating recognition of alignment marks of semiconductor packages according to an embodiment;

FIGS. 13 to 15 are cross-sectional views illustrating a method of manufacturing an alignment mark of a semiconductor package according to an embodiment;

FIGS. 16 and 17 are cross-sectional views illustrating a method of manufacturing an alignment mark of a semiconductor package according to an embodiment;

FIGS. 18 to 22 are cross-sectional views illustrating a method of manufacturing an alignment mark of a semiconductor package according to an embodiment;

FIG. 23 is a cross-sectional view of a semiconductor package according to an embodiment;

FIG. 24 is a block diagram illustrating a configuration of a semiconductor package according to an embodiment; and

FIG. 25 is a block diagram schematically illustrating a configuration of a semiconductor package according to an embodiment.

### DETAILED DESCRIPTION OF EMBODIMENTS

Hereinafter, embodiments of the disclosure will be described in detail with reference to the accompanying drawings. Like reference numerals refer to like elements throughout and redundant description thereof will not always be given.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

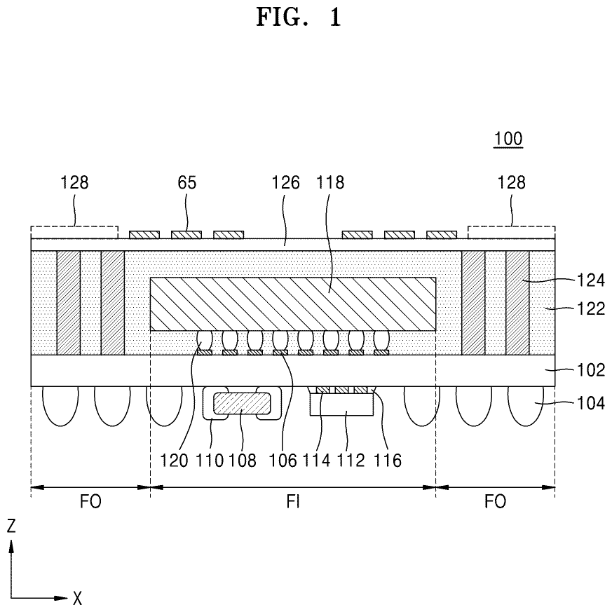

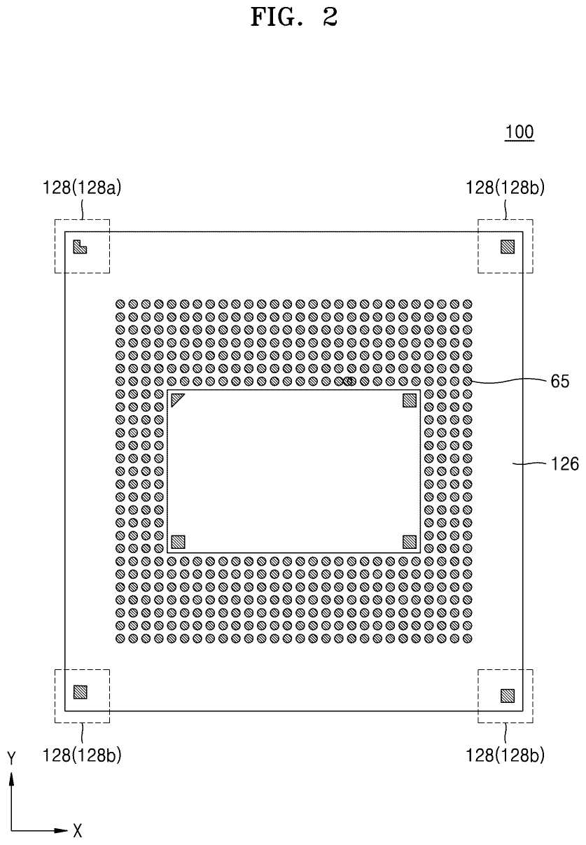

FIG. 1 is a cross-sectional view of a semiconductor package 100 according to an embodiment and FIG. 2 is a schematic top plan view of the semiconductor package 100 of FIG. 1.

Specifically, the semiconductor package 100 may include a base structure 102, a semiconductor chip 118, a package body layer 122, metal post layers 124, and a redistribution structure 126. The base structure 102 may include a fan-in area FI and fan-out areas FO surrounding the fan-in area FI.

The semiconductor package 100 of FIG. 1 is described by using a fan-out wafer level package (FOWLP) manufactured at a wafer level. However, the disclosure may also be applied to a panel level package, that is, a fan-out panel level package (FOPLP) manufactured at a panel level.

In the cross-sectional view of FIG. 1, the fan-out areas FO may be at both sides of the fan-in area FI. In some embodiments, the base structure 102 may include a lower redistribution structure. The lower redistribution structure may include a lower redistribution layer and a lower redistribution insulating layer insulating the lower redistribution layer. In some embodiments, the base structure 102 may include a wiring board.

External connection terminals 104 may be attached to a bottom surface of the base structure 102. The external connection terminals 104 may include, for example, solder balls or solder bumps. The external connection terminals 104 may electrically connect the semiconductor package 100 to an external device.

In some embodiments, passive elements 108 and 112 may be arranged on the bottom surface of the base structure 102. The passive elements 108 and 112 may include a first passive element 108 and a second passive element 112. The first passive element 108 may be connected to the base structure 102 by a first manual connection member 110.

The second passive element 112 may be connected to the base structure 102 by a second manual connection member 114. The second passive element 112 may be attached to the base structure 102 by an underfill material 116.

Chip connection pads 106 may be arranged on a top surface of the base structure 102. A semiconductor chip 118 electrically connected to the chip connection pads 106 may be arranged in the fan-in area FI of the top surface of the base structure 102. The semiconductor chip 118 may be electrically connected to the chip connection pads 106 through chip connection terminals 120. The chip connection terminals 120 may include, for example, solder balls or solder bumps.

The semiconductor chip 118 may include a central processing unit (CPU), a micro-processing unit (MPU), a graphics processing unit (GPU), or an application processor (AP). The semiconductor chip 118 may include a controller chip for controlling an upper semiconductor chip to be described later.

The package body layer 122 may be arranged in the fan-in area FI and the fan-out areas FO and may cover the semiconductor chip 118. In some embodiments, the package body layer 122 may include a molding layer. The molding layer may include, for example, an epoxy molding compound (EMC). Although the molding layer is illustrated as covering the semiconductor chip 118, the disclosure is not limited thereto. In some embodiments, the molding layer may be formed only in the fan-in area FI, and the fan-out areas FO may include the wiring board.

The redistribution structure 126 may be arranged on the package body layer 122. The redistribution structure 126 may be arranged on both the fan-in area FI and the fan-out areas FO. As illustrated in FIGS. 1 and 2, the redistribution structure 126 may be arranged on an entire surface of the package body layer 122.

The redistribution structure 126 may include an upper redistribution structure. The upper redistribution structure may include an upper redistribution layer and an upper redistribution insulating layer insulating the upper redistribution layer. A plurality of external connection pads 65 for electrically connecting the redistribution structure 126 to an upper semiconductor package may be arranged on the redistribution structure 126. As shown in FIG. 2, the distance from the alignment marks 128 to the edges of the redistribution structure 126 is smaller than the distance from the external connection pads 65 to the edges of the redistribution structure 126.

The plurality of, for example, tens to hundreds of, external connection pads 65 may be arranged on the redistribution structure 126. It is illustrated as an example that more external connection pads 65 are arranged in FIG. 2 than in FIG. 1. The plurality of external connection pads 65 may be connected to a plurality of package connection terminals to be described later.

The semiconductor package 100 may include alignment marks 128 capable of aligning the upper semiconductor package that is additionally stacked. The alignment marks 128 may be formed near left and right edges of the redistribution structure 126 in the cross-sectional view of FIG. 1. As illustrated in FIG. 2, the alignment marks 128 may be positioned near the edges of the redistribution structure 126. For example, a distance from the edges of the redistribution structure 126 to the alignment marks 128 may be smaller than a distance from the edges of the redistribution structure 126 to the external connection pads 65.

In some embodiments, the alignment marks 128 may be arranged near at least one of the edges of the redistribution structure 126. The alignment marks 128 may include an angled first alignment mark 128a and square second alignment marks 128b. In some embodiments, the alignment marks 128 may be triangular or circular unlike in FIG. 2.

In some embodiments, the alignment marks 128 may be arranged on or in the redistribution structure 126. In some embodiments, the alignment marks 128 may be at the same level as that of the plurality of external connection pads 65, or at a level lower than that of the plurality of external connection pads 65.

In the semiconductor package 100, as described later, a plurality of auxiliary patterns are arranged in the redistribution structure 126 under the alignment marks 128 to assist in recognition of the alignment marks 128 by a vision camera. The auxiliary patterns will be described in detail later.

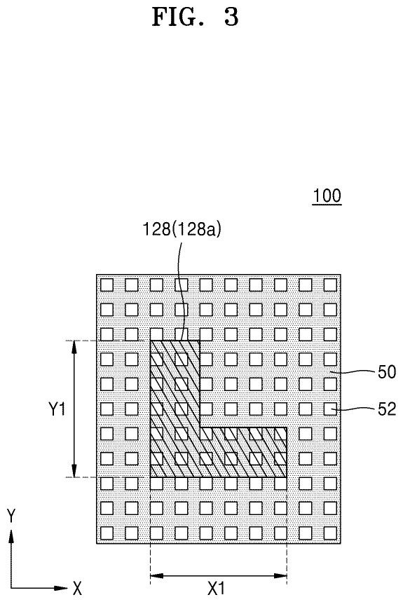

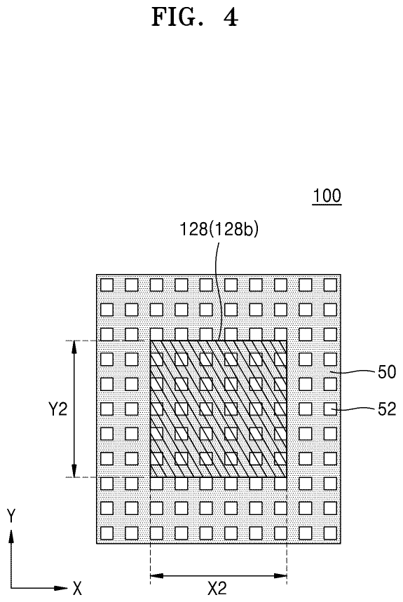

FIGS. 3 and 4 are plan views each illustrating an alignment mark 128 and a plurality of auxiliary patterns 50 of the semiconductor package 100 of FIGS. 1 and 2.

Specifically, as illustrated in each of FIGS. 3 and 4, the alignment mark 128 is arranged on the plurality of auxiliary patterns 50. The alignment mark 128 may include a metal layer. In some embodiments, the alignment mark 128 may include a plurality of metal layers as described later. The plurality of auxiliary patterns 50 may be arranged under the alignment mark 128 to assist in recognition of the alignment mark 128 by the vision camera. When the plurality of auxiliary patterns 50 are formed under the alignment mark 128, the alignment mark 128 may be easily recognized by the vision camera due to diffuse reflection of light, which is caused by the plurality of auxiliary patterns 50.

The plurality of auxiliary patterns 50 may include a redistribution layer. The plurality of auxiliary patterns 50 may include a metal layer, for example, a copper (Cu) layer. The plurality of auxiliary patterns 50 may be partitioned by a redistribution insulating layer (or a redistribution insulating pattern) 52. The plurality of auxiliary patterns 50 and the redistribution insulating layer (or the redistribution insulating pattern) 52 will be described in detail later.

The angled first alignment mark 128a is illustrated in FIG. 3. A size of the angled first alignment mark 128a may be X1 and Y1 in X and Y directions, respectively. In some embodiments, each of X1 and Y1 may be 100 μm to 400 μm.

The square second alignment mark 128b is illustrated in FIG. 4. A size of the square second alignment mark 128b may be X2 and Y2 in the X and Y directions, respectively. In some embodiments, each of X2 and Y2 may be 100 μm to 400 μm.

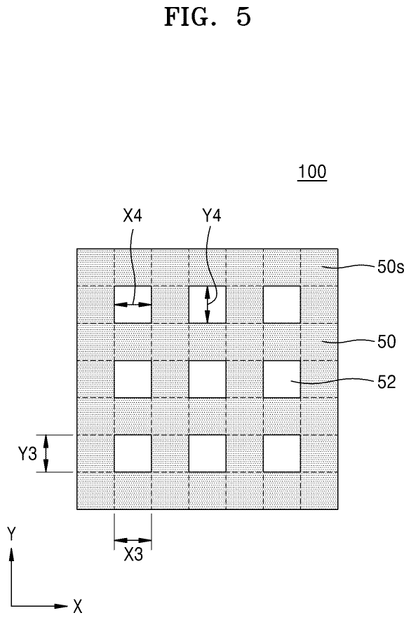

FIG. 5 is an enlarged plan view illustrating the plurality of auxiliary patterns 50 of the semiconductor package 100 of FIGS. 1 and 2.

Specifically, the plurality of auxiliary patterns 50 may include a plurality of sub auxiliary patterns 50s apart from one another in the X direction and a Y direction perpendicular to the X direction. The plurality of sub auxiliary patterns 50s may be separated by the redistribution insulating layer (or the redistribution insulating pattern) 52.

The plurality of sub auxiliary patterns 50s and the redistribution insulating layer (or the redistribution insulating pattern) 52 may form a mesh-type pattern. The mesh-type pattern may include a metal mesh-type pattern. The redistribution insulating layer 52 may include a transparent insulating material. The redistribution insulating layer 52 may include a transparent organic layer. The redistribution insulating layer 52 may include a photo imageable dielectric (PID) layer.

A size of each of the plurality of sub auxiliary patterns 50s may be X3 and Y3 in the X and Y directions, respectively. X3 and Y3 may have the same value. In some embodiments, each of X3 and Y3 may be 1.8 μm to 30 μm In some embodiments, each of X3 and Y3 may be 5 μm, 10 μm, or 20 μm

A size of the redistribution insulating layer (or the redistribution insulating pattern) 52 may be equal to that of each of the plurality of sub auxiliary patterns 50s. In some embodiments, the size of the redistribution insulating layer (or the redistribution insulating pattern) 52 may be X4 and Y4 in the X and Y directions, respectively. X4 and Y4 may have the same value. In some embodiments, each of X4 and Y4 may be 1.8 nm to 30 nm. Each of X4 and Y4 may be 5 nm, 10 nm, or 20 μm.

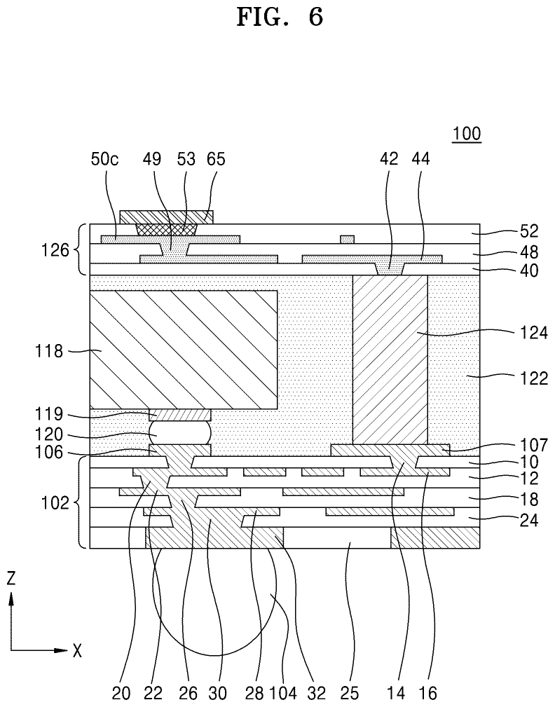

FIG. 6 is an enlarged cross-sectional view illustrating an enlarged part of the semiconductor package of FIG. 1 according to an embodiment.

Specifically, in FIG. 6, reference numerals that are the same as those of FIG. 1 denote the same elements. In FIG. 6, description previously given with reference to FIG. 1 is briefly given or omitted. As illustrated in FIG. 6, the semiconductor package 100 may include a base structure 102, a semiconductor chip 118, a package body layer 122, a metal post layer 124, a redistribution structure 126, and an external connection pad 65.

The base structure 102 may include a lower redistribution structure. The base structure 102 may include first to fifth lower redistribution insulating layers 10, 12, 18, 24, and 25, first to fourth lower redistribution layers 16, 22, 28, and 32, and first to fourth lower redistribution vias 14, 20, 26, and 30.

In some embodiments, the first to fourth lower redistribution layers 16, 22, 28, and 32 and the first to fourth lower redistribution vias 14, 20, 26, and 30 may include a metal layer, for example, a Cu layer. In some embodiments, the first to fifth lower redistribution insulating layers 10, 12, 18, 24, and 25 may include an insulating layer, for example, a PID layer.

The first lower redistribution via 14 may be electrically connected to a post connection pad 107 and a chip connection pad 106. The second lower redistribution via 20 may electrically connect the first lower redistribution layer 16 to the second lower redistribution layer 22. The third lower redistribution via 26 may electrically connect the second lower redistribution layer 22 to the third lower redistribution layer 28.

The fourth lower redistribution via 30 may electrically connect the third lower redistribution layer 28 to the fourth lower redistribution layer 32. The fourth lower redistribution layer 32 may include a barrier metal layer. The fourth lower redistribution layer 32 may be connected to an external connection terminal 104.

The semiconductor chip 118 may be arranged on a top surface of the base structure 102. A chip pad 119 of the semiconductor chip 118 may be electrically connected to the chip connection pad 106 through a chip connection terminal 120. The package body layer 122 may be formed on the top surface of the base structure 102 to seal the semiconductor chip 118. The package body layer 122 may include a molding layer.

The metal post layer 124 may be arranged in the package body layer 122 on the post connection pad 107. The metal post layer 124 may include a metal layer, for example, a Cu layer. The metal post layer 124 may be electrically connected to the base structure 102. The redistribution structure 126 may be arranged on the package body layer 122. The redistribution structure 126 may include an upper redistribution structure.

The redistribution structure 126 may include first to third upper redistribution insulating layers 40, 48, and 52, first and second upper redistribution layers 44 and 50c, and first to third upper redistribution vias 42, 49, and 53. The second upper redistribution layer 50c may be positioned at the uppermost part of the redistribution structure 126.

In some embodiments, the first and second upper redistribution layers 44 and 50c and the first and second upper redistribution vias 42 and 49 may include a metal layer, for example, a Cu layer. In some embodiments, the third upper redistribution via 53 may include a metal layer, for example, a nickel (Ni) layer.

In some embodiments, the first to third upper redistribution insulating layers 40, 48, and 52 may include a transparent insulating material. The first to third upper redistribution insulating layers 40, 48, and 52 may include a transparent organic layer. The first to third upper redistribution insulating layers 40, 48, and 52 may include a PID layer.

The external connection pad 65 for electrically connecting the redistribution structure 126 to the upper semiconductor package may be arranged on the redistribution structure 126. The external connection pad 65 may include a plurality of metal layers. The external connection pad 65 may include a triple metal layer. The external connection pad 65 may be at the same level as that of an alignment mark 128 to be described later. In some embodiments, the external connection pad 65 may include the same material as that of an alignment mark to be described later.

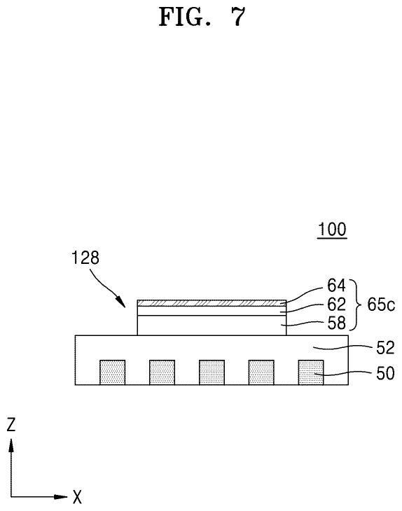

FIG. 7 is an enlarged cross-sectional view illustrating an alignment mark 128 and a plurality of auxiliary patterns 50 of the semiconductor package 100 of FIG. 1 according to an embodiment.

Specifically, the alignment mark 128 and the plurality of auxiliary patterns 50 illustrated in FIG. 7 may be applied to the semiconductor package 100 of FIGS. 1 and 6. Therefore, in FIG. 7, reference numerals that are the same as those of FIGS. 1 and 6 denote the same elements. In FIG. 7, description previously given with reference to FIGS. 1 and 6 is briefly given or omitted.

The semiconductor package 100 may include the plurality of auxiliary patterns 50 apart from one another in the X direction. The plurality of auxiliary patterns 50 may be at the same level as that of the second upper redistribution layer 50c of FIG. 6. The third upper redistribution insulating layer 52 may be formed on and among the plurality of auxiliary patterns 50. In some embodiments, the plurality of auxiliary patterns 50 may include dummy patterns to which electricity is not applied.

The third upper redistribution insulating layer 52 of FIG. 7 may be at the same level as that of the third upper redistribution insulating layer 52 of FIG. 6. Because a flat layout of the plurality of auxiliary patterns 50 and the third upper redistribution insulating layer 52 has been described with reference to FIGS. 3 to 5, description thereof will not be given.

The alignment mark 128 may be arranged on the third upper redistribution insulating layer 52. The plurality of auxiliary patterns 50 and the third upper redistribution insulating layer 52 may be arranged under the alignment mark 128. The plurality of auxiliary patterns 50 may be arranged in the third upper redistribution insulating layer 52 under the alignment mark 128.

The alignment mark 128 may include a plurality of metal layers. In some embodiments, the alignment mark 128 may include a triple metal layer 65c. The triple metal layer 65c may be at the same level as that of the external connection pad 65 of FIG. 6. The alignment mark 128 may include a first metal layer 58, a second metal layer 62, and a third metal layer 64. In some embodiments, the first metal layer 58 may include a Cu layer, the second metal layer 62 may include a Ni layer, and the third metal layer 64 may include a gold (Au) layer. The uppermost metal layer of the alignment mark 128 may include an Au layer.

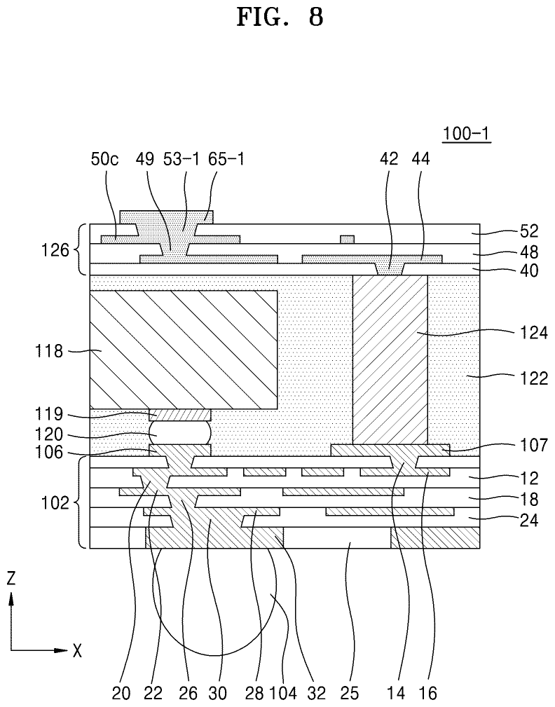

FIG. 8 is an enlarged cross-sectional view illustrating an enlarged part of a semiconductor package 100-1 according to an embodiment.

Specifically, the semiconductor package 100-1 may be the same as the semiconductor package 100 of FIG. 6 except for a configuration of a third upper redistribution via 53-1 and a configuration of an external connection pad 65-1. In FIG. 8, reference numerals that are the same as those of FIGS. 1 and 6 denote the same elements. In FIG. 8, description previously given with reference to FIGS. 1 and 6 is briefly given or omitted.

The semiconductor package 100-1 may include a base structure 102, a semiconductor chip 118, a package body layer 122, a metal post layer 124, a redistribution structure 126, and the external connection pad 65-1. Because the base structure 102, the semiconductor chip 118, the package body layer 122, and the metal post layer 124 have been described above, description thereof will not be given.

The redistribution structure 126 may include first to third upper redistribution insulating layers 40, 48, and 52, first and second upper redistribution layers 44 and 50c, and first to third upper redistribution vias 42, 49, and 53-1. The first and second upper redistribution layers 44 and 50c and the first to third upper redistribution vias 42, 49, and 53-1 may include a metal layer, for example, a Cu layer.

The external connection pad 65-1 may include a double metal layer. The external connection pad 65-1 may be at the same level as that of an alignment mark 128-1 to be described later. In some embodiments, the external connection pad 65-1 may include the same material as that of an alignment mark to be described later.

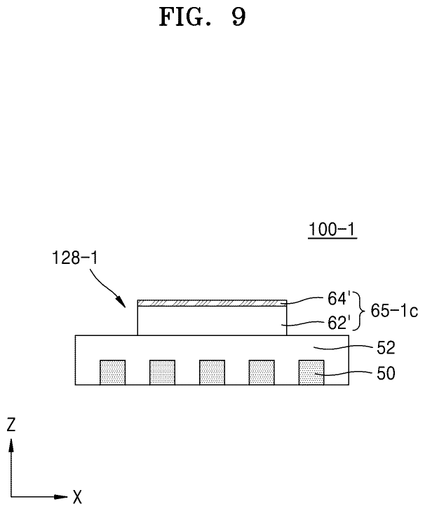

FIG. 9 is an enlarged cross-sectional view illustrating the alignment mark 128-1 and the plurality of auxiliary patterns 50 of the semiconductor package 100-1 according to an embodiment.

Specifically, the alignment mark 128-1 and the plurality of auxiliary patterns 50 illustrated in FIG. 9 may be applied to the semiconductor package 100-1 of FIG. 8. In FIG. 9, reference numerals that are the same as those of FIG. 7 denote the same elements. In FIG. 9, description previously given with reference to FIG. 7 is briefly given or omitted.

The semiconductor package 100-1 may include the plurality of auxiliary patterns 50 apart from one another in the X direction. The plurality of auxiliary patterns 50 may be at the same level as that of the second upper redistribution layer 50c of FIG. 8. The third upper redistribution insulating layer 52 of FIG. 9 may be at the same level as that of the third upper redistribution insulating layer 52 of FIG. 8.

The alignment mark 128-1 may be arranged on the third upper redistribution insulating layer 52. The plurality of auxiliary patterns 50 and the third upper redistribution insulating layer 52 may be arranged under the alignment mark 128-1. The plurality of auxiliary patterns 50 may be arranged in the third upper redistribution insulating layer 52 under the alignment mark 128-1.

The alignment mark 128-1 may include a double metal layer 65-1c. The double metal layer 65-1c may be at the same level as that of the external connection pad 65-1 of FIG. 8. The alignment mark 128-1 may include a first metal layer 62′ and a second metal layer 64′. In some embodiments, the first metal layer 62′ may include a Ni layer, and the second metal layer 64′ may include an Au layer. The uppermost metal layer of the alignment mark 128-1 may include an Au layer.

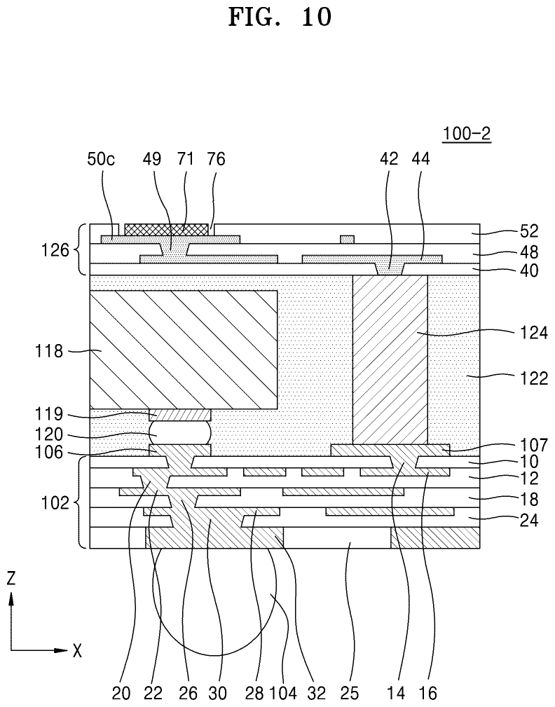

FIG. 10 is an enlarged cross-sectional view illustrating an enlarged part of a semiconductor package 100-2 according to an embodiment.

Specifically, the semiconductor package 100-2 may be substantially the same as the semiconductor package 100 of FIG. 6 except for a configuration of an external connection pad 71. In FIG. 10, reference numerals that are the same as those of FIGS. 1 and 6 denote the same elements. In FIG. 10, description previously given with reference to FIGS. 1 and 6 is briefly given or omitted.

The semiconductor package 100-2 may include a base structure 102, a semiconductor chip 118, a package body layer 122, a metal post layer 124, a redistribution structure 126, and the external connection pad 71. Because the base structure 102, the semiconductor chip 118, the package body layer 122, and the metal post layer 124 have been described above, description thereof will not be given.

The redistribution structure 126 may include first to third upper redistribution insulating layers 40, 48, and 52, first and second upper redistribution layers 44 and 50c, and first and second upper redistribution vias 42 and 49. The first and second upper redistribution layers 44 and 50c and the first and second upper redistribution vias 42 and 49 may include a metal layer, for example, a Cu layer.

The external connection pad 71 may be in contact with the second upper redistribution layer 50c. The external connection pad 71 may be in direct contact with the second upper redistribution layer 50c. The external connection pad 71 is separated from the third upper redistribution insulating layer 52 by exposure holes 76. The external connection pad 71 may not be in contact with the third upper redistribution insulating layer 52.

The external connection pad 71 may include a plurality of metal layers. The external connection pad 71 may include a double metal layer. The external connection pad 71 may be at the same level as that of an alignment mark 128-2 to be described later. In some embodiments, the external connection pad 71 may include the same material as that of an alignment mark to be described later.

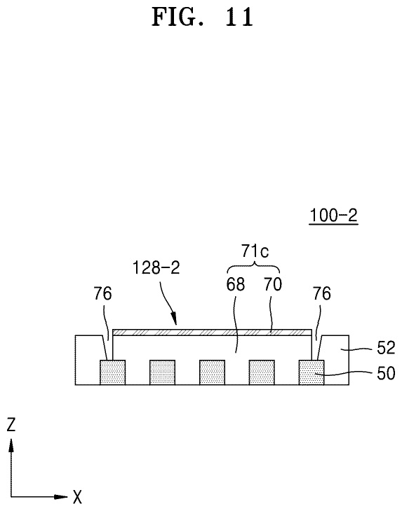

FIG. 11 is an enlarged cross-sectional view illustrating the alignment mark 128-2 and the plurality of auxiliary patterns 50 of the semiconductor package 100-2 according to an embodiment.

Specifically, the alignment mark 128-2 and the plurality of auxiliary patterns 50 illustrated in FIG. 11 may be applied to the semiconductor package 100-2 of FIG. 10. In FIG. 11, reference numerals that are the same as those of FIG. 7 denote the same elements. In FIG. 11, description previously given with reference to FIG. 7 is briefly given or omitted.

The semiconductor package 100-2 may include the plurality of auxiliary patterns 50 apart from one another in the X direction. The plurality of auxiliary patterns 50 may be at the same level as that of the second upper redistribution layer 50c of FIG. 10. The third upper redistribution insulating layer 52 of FIG. 11 may be at the same level as that of the third upper redistribution insulating layer 52 of FIG. 10.

The alignment mark 128-2 may be arranged in the third upper redistribution insulating layer 52. The plurality of auxiliary patterns 50 may be arranged under the alignment mark 128-2. The plurality of auxiliary patterns 50 may be arranged in the third upper redistribution insulating layer 52 under the alignment mark 128-1.

The alignment mark 128-2 may be in contact with the plurality of auxiliary patterns 50. The alignment mark 128-2 may be in direct contact with the plurality of auxiliary patterns 50. The alignment mark 128-2 is separate from the third upper redistribution insulating layer 52 by the exposure holes 76. The plurality of auxiliary patterns 50 may be exposed by the exposure holes 76 under the alignment mark 128-2. The alignment mark 128-2 may not be in contact with the third upper redistribution insulating layer 52.

The alignment mark 128-2 may include a plurality of metal layers. The alignment mark 128-2 may include a double metal layer 71c. The double metal layer 71c may be at the same level as that of the external connection pad 71 of FIG. 10. The alignment mark 128-2 may include a first metal layer 68 and a second metal layer 70. In some embodiments, the first metal layer 68 may include a Ni layer, and the second metal layer 70 may include an Au layer. The uppermost metal layer of the alignment mark 128-2 may include an Au layer.

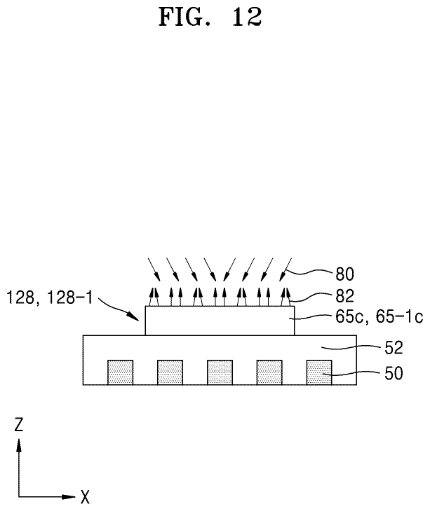

FIG. 12 is a cross-sectional view illustrating recognition of the alignment marks 128 and 128-1 of the semiconductor packages 100 and 100-1 according to the disclosure.

Specifically, the semiconductor packages 100 and 100-1 (refer to FIGS. 7 and 9) according to the disclosure may include the plurality of auxiliary patterns 50, the third upper redistribution insulating layer 52, and the alignment marks 128 and 128-1, respectively. In FIG. 12, for convenience sake, the plurality of auxiliary patterns 50 and the alignment marks 128 and 128-1 described with reference to FIGS. 7 and 9 are illustrated. The alignment mark 128 may include the triple metal layer 65c. The alignment mark 128-1 may include the double metal layer 65-1c.

Light 80 may be incident on the alignment marks 128 and 128-1, the plurality of auxiliary patterns 50, and the third upper redistribution insulating layer 52 by the vision camera. In other words, light 80 may be incident on the alignment marks 128 and 128-1, the plurality of auxiliary patterns 50, and the third upper redistribution insulating layer 52 at various angles.

When the plurality of auxiliary patterns 50 are formed under the alignment mark 128, the incident light 80 may be scattered due to the plurality of auxiliary patterns 50 to emit light 82. In addition, when the alignment marks 128 and 128-1 include a plurality of metal layers, for example, the triple metal layer 65c or the double metal layer 65-1c, the incident light 80 may be reflected from the alignment marks 128 and 128-1 at various angles so that light 82 may be emitted. In addition, when the uppermost metal layer of the alignment marks 128 and 128-1 includes Au, reflectivity of the incident light 80 may be increased.

As a result, the reflected light 82 may be emitted at various angles due to the alignment marks 128 and 128-1 or the plurality of auxiliary patterns 50. The light 82 reflected and emitted at various angles may be incident on the vision camera to easily recognize the alignment marks 128 and 128-1.

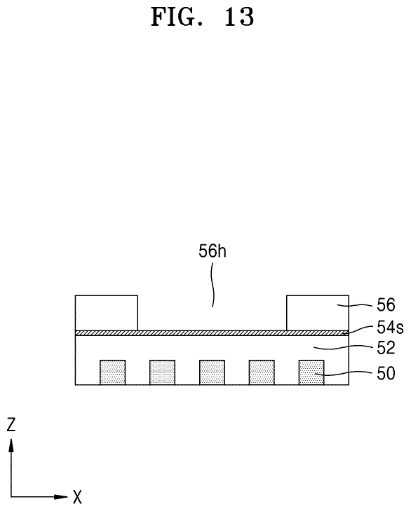

FIGS. 13 to 15 are cross-sectional views illustrating a method of manufacturing the alignment mark 128 of the semiconductor package 100, according to an embodiment.

Specifically, FIGS. 13 to 15 illustrate a method of manufacturing the alignment mark 128 of the semiconductor package 100 of FIGS. 6 and 7. In FIGS. 13 to 15, description previously given with reference to FIGS. 6 and 7 is briefly given or omitted.

Referring to FIG. 13, the third upper redistribution insulating layer 52 is formed on the plurality of auxiliary patterns 50. The third upper redistribution insulating layer 52 may be formed on and among the plurality of auxiliary patterns 50. The third upper redistribution insulating layer 52 may include a transparent insulating material, for example, a PID layer.

A metal seed layer 54s is formed on the third upper redistribution insulating layer 52. In some embodiments, the metal seed layer 54s may include a Cu seed layer. Subsequently, a mask pattern 56 having a contact hole 56h exposing a part of the metal seed layer 54s is formed on the metal seed layer 54s. The mask pattern 56 includes a photoresist pattern.

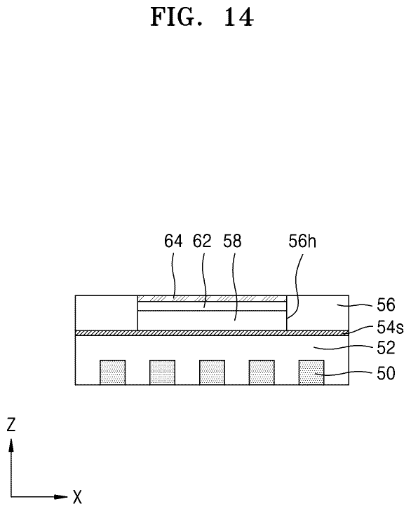

Referring to FIG. 14, a first metal layer 58, a second metal layer 62, and a third metal layer 64 are sequentially formed in the contact hole 56h on the metal seed layer 54s. The first metal layer 58, the second metal layer 62, and the third metal layer 64 are formed by electroplating. The first metal layer 58 includes a Cu layer, the second metal layer 62 includes a Ni layer, and the third metal layer 64 includes an Au layer.

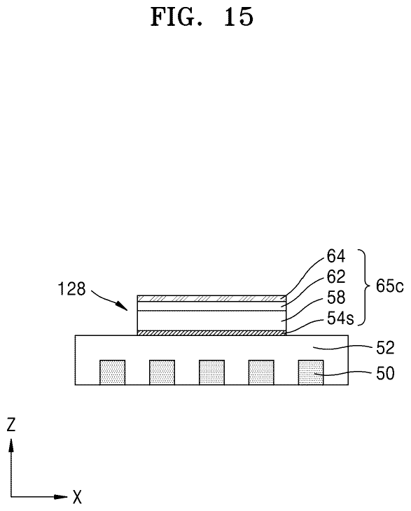

Referring to FIG. 15, the mask pattern 56 is removed. When the mask pattern 56 is removed, the metal seed layer 54s under the mask pattern 56 may also be partially etched. The alignment mark 128 may be formed on the third upper redistribution insulating layer 52 by such a process.

The alignment mark 128 may include the metal seed layer 54s including a Cu layer, the first metal layer 58 including a Cu layer, the second metal layer 62 including a Ni layer, and the third metal layer 64 including an Au layer. The metal seed layer 54s and the first metal layer 58 including the same material may form one layer. As a result, the alignment mark 128 may include the triple metal layer 65c. The uppermost metal layer of the alignment mark 128 may include an Au layer.

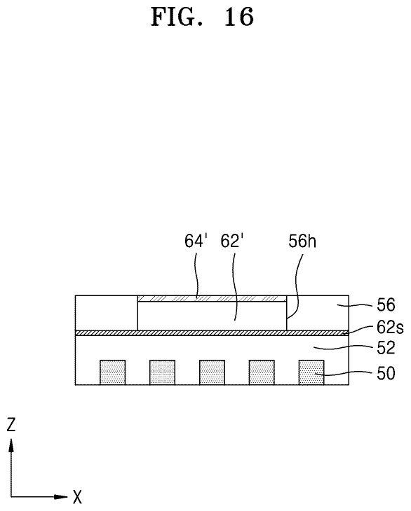

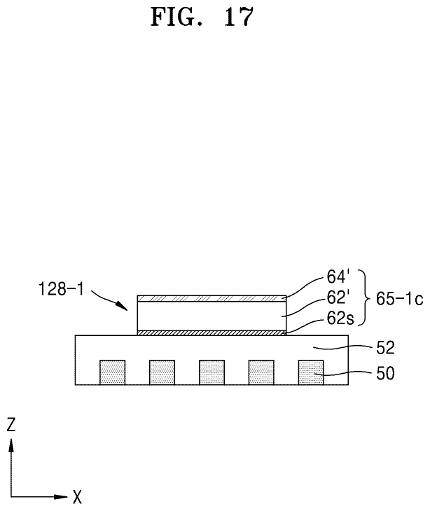

FIGS. 16 and 17 are cross-sectional views illustrating a method of manufacturing the alignment mark 128-1 of the semiconductor package 100-1 according to an embodiment.

Specifically, FIGS. 16 and 17 illustrate a method of manufacturing the alignment mark 128-1 of the semiconductor package 100-1 of FIGS. 8 and 9. In FIGS. 16 and 17, description previously given with reference to FIGS. 8 and 9 is briefly given or omitted.

Referring to FIG. 16, the third upper redistribution insulating layer 52 is formed on the plurality of auxiliary patterns 50. The third upper redistribution insulating layer 52 may be formed on and among the plurality of auxiliary patterns 50. The third upper redistribution insulating layer 52 may include a transparent insulating material, for example, a PID layer.

A metal seed layer 62s is formed on the third upper redistribution insulating layer 52. In some embodiments, the metal seed layer 62s may include a Ni seed layer. Subsequently, the mask pattern 56 having the contact hole 56h exposing a part of the metal seed layer 62s is formed on the metal seed layer 62s. The mask pattern 56 includes a photoresist pattern.

Subsequently, the first metal layer 62′ and the second metal layer 64′ are sequentially formed in the contact hole 56h on the metal seed layer 62s. The first metal layer 62′ and the second metal layer 64′ are formed by electroplating. The first metal layer 62′ includes a Ni layer, and the second metal layer 64′ includes an Au layer.

Referring to FIG. 17, the mask pattern 56 is removed. When the mask pattern 56 is removed, the metal seed layer 62s under the mask pattern 56 may also be partially etched. The alignment mark 128-1 may be formed on the third upper redistribution insulating layer 52 by such a process.

The alignment mark 128-1 may include the metal seed layer 62s including a Ni layer, the first metal layer 62′ including a Ni layer, and the second metal layer 64′ including an Au layer. The metal seed layer 62s and the first metal layer 62′ including the same material may form one layer. As a result, the alignment mark 128-1 may include the double metal layer 65-1c. The uppermost metal layer of the alignment mark 128-1 may include an Au layer.

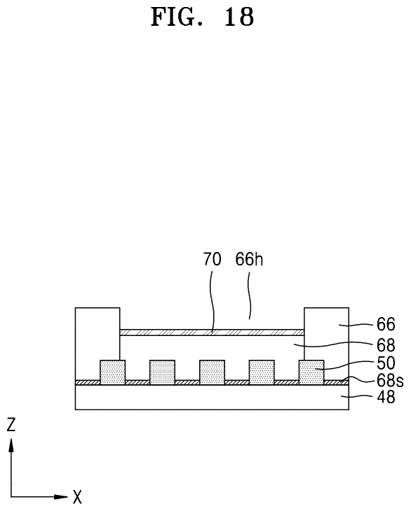

FIGS. 18 to 22 are cross-sectional views illustrating a method of manufacturing the alignment mark 128-2 of the semiconductor package 100-2 according to an embodiment.

Specifically, FIGS. 18 to 22 illustrate a method of manufacturing the alignment mark 128-2 of the semiconductor package 100-2 of FIGS. 10 and 11. In FIGS. 18 to 22, description previously given with reference to FIGS. 10 and 11 is briefly given or omitted.

Referring to FIG. 18, the plurality of auxiliary patterns 50 are formed on the second upper redistribution insulating layer 48. A metal seed layer 68s is formed among the plurality of auxiliary patterns 50 on the second upper redistribution insulating layer 48. The metal seed layer 68s includes a Ni layer.

A first mask pattern 66 having the metal seed layer 68s and a first contact hole 66h exposing parts of the plurality of auxiliary patterns 50 is formed on the plurality of auxiliary patterns 50 and the metal seed layer 68s. The first mask pattern 66 includes a photoresist pattern.

Subsequently, the first metal layer 68 and the second metal layer 70 are sequentially formed in the first contact hole 66h on the metal seed layer 68s and the plurality of auxiliary patterns 50. The first metal layer 68 and the second metal layer 70 are formed by electroplating.

The first metal layer 68 includes a Ni layer, and the second metal layer 70 includes an Au layer. The first metal layer 68 is formed on the plurality of auxiliary patterns 50 while filling a space among the plurality of auxiliary patterns 50 on the metal seed layer 68s. The first metal layer 68 may be in contact with the plurality of auxiliary patterns 50.

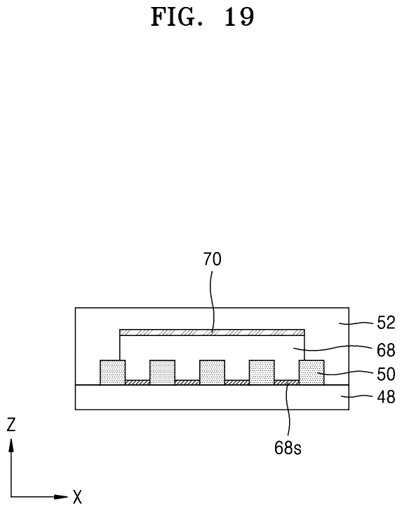

Referring to FIG. 19, the first mask pattern 66 is removed. When the first mask pattern 66 is removed, the metal seed layer 68s under the first mask pattern 66 may also be partially etched. Subsequently, the third upper redistribution insulating layer 52 is formed on the second upper redistribution insulating layer 48 to cover the plurality of auxiliary patterns 50, the first metal layer 68, and the second metal layer 70. The third upper redistribution insulating layer 52 includes a transparent insulating material, for example, a PID layer.

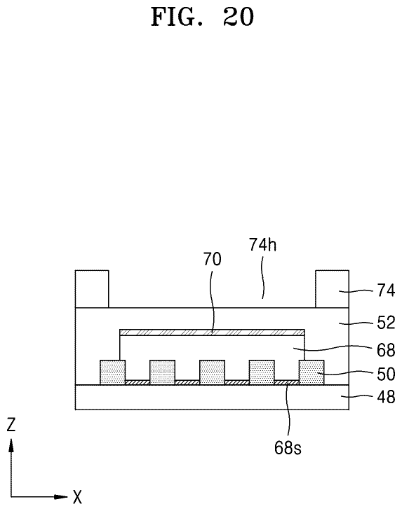

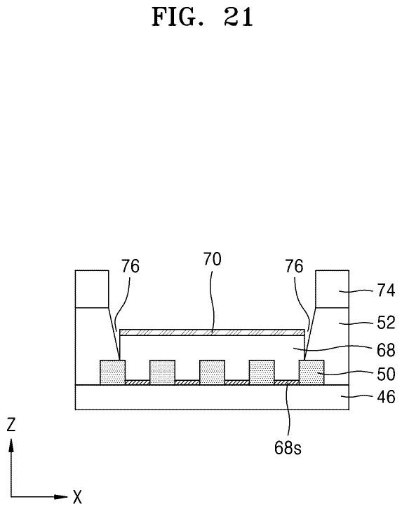

Referring to FIGS. 20 and 21, as illustrated in FIG. 20, a second mask pattern 74 having a second contact hole 74h exposing a part of the third upper redistribution insulating layer 52 is formed on the third upper redistribution insulating layer 52. The second mask pattern 74 includes a photoresist pattern. The second mask pattern 74 is formed on (e.g., above) the outermost auxiliary patterns 50.

As illustrated in FIG. 21, the exposure holes 76 are formed by etching the third upper redistribution insulating layer 52 in the second contact hole 74h by using the second mask pattern 74 as an etching mask. The exposure holes 76 may be separation holes separating the first metal layer 68 and the second metal layer 70 from the third upper redistribution insulating layer 52. The exposure holes 76 may expose tops of the auxiliary patterns 50.

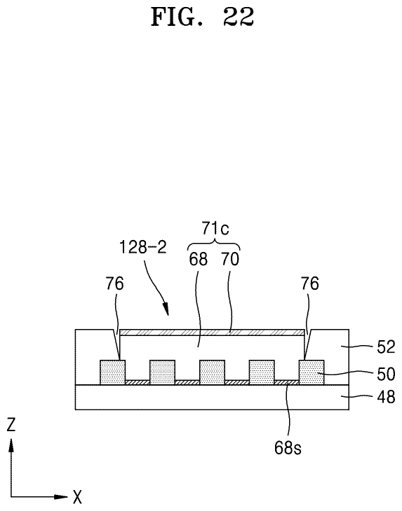

Referring to FIG. 22, the second mask pattern 74 (refer to FIG. 21) is removed. Through such a process, the alignment mark 128-2 may be formed in the third upper redistribution insulating layer 52. The alignment mark 128-2 may include the metal seed layer 68s including a Ni layer, the first metal layer 68 including a Ni layer, and the second metal layer 70 including an Au layer.

The metal seed layer 68s and the first metal layer 68 including the same material may form one layer. Accordingly, the alignment mark 128-2 may include the double metal layer 71c. The uppermost metal layer of the alignment mark 128-2 may include an Au layer.

The alignment mark 128-2 may be in direct contact with the plurality of auxiliary patterns 50. The alignment mark 128-2 is separated from the third upper redistribution insulating layer 52 by the exposure holes 76. The plurality of auxiliary patterns 50 may be exposed by the exposure holes 76 under the alignment mark 128-2. The alignment mark 128-2 may not be in contact with the third upper redistribution insulating layer 52.

Each of the semiconductor packages 100, 100-1, and 100-2 according to the disclosure may include the plurality of auxiliary patterns 50 for recognizing each of the alignment marks 128, 128-1, and 128-2 on or in the redistribution structure 126. Accordingly, in each of the semiconductor packages 100, 100-1, and 100-2 according to the disclosure, the upper semiconductor package may be precisely aligned by using each of the alignment marks 128, 128-1, and 128-2 above the plurality of auxiliary patterns 50 to be stacked.

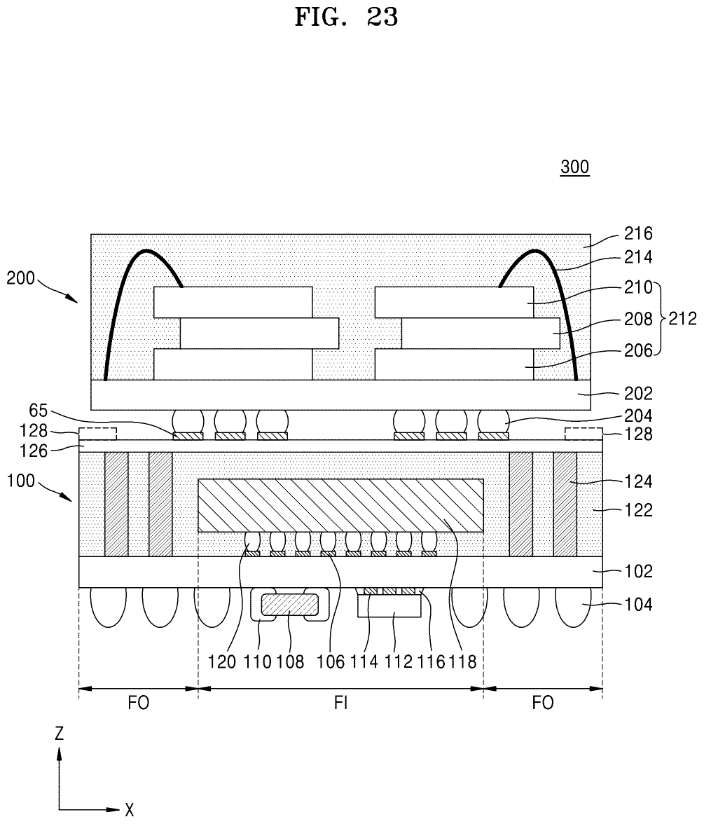

FIG. 23 is a cross-sectional view of a semiconductor package 300 according to an embodiment.

Specifically, the semiconductor package 300 may include a lower semiconductor package 100 and an upper semiconductor package 200. The semiconductor package 300 may include a package on package (POP)-type stacked semiconductor package in which the upper semiconductor package 200 is attached onto the lower semiconductor package 100.

The semiconductor package 100 illustrated in FIGS. 1 to 7 may be used as the lower semiconductor package 100. Each of the semiconductor packages 100-1 and 100-2 illustrated in FIGS. 8 to 11 may be used as the lower semiconductor package 100. Because the lower semiconductor package 100 has been described above with reference to FIGS. 1 to 7, description previously given with reference to FIGS. 1 to 7 is briefly given or omitted.

The lower semiconductor package 100 may include the redistribution structure 126. The plurality of external connection pads 65 may be arranged on the redistribution structure 126. The alignment marks 128 may be formed on the left and right sides of the redistribution structure 126. As described above, the alignment marks 128 may be positioned near the edges of the redistribution structure 126 in a plan view.

The alignment marks 128 may be arranged on or in the redistribution structure 126. In some embodiments, the alignment marks 128 may be at the same level as that of the plurality of external connection pads 65, or at a level lower than that of the plurality of external connection pads 65.

The alignment marks 128 may be formed to align the upper semiconductor package 200 when the upper semiconductor package 200 is stacked. The alignment marks 128 may be recognition patterns that may be recognized by the vision camera when the upper semiconductor package 200 is mounted on the lower semiconductor package 100. Because the alignment marks 128 have been described above with reference to FIGS. 1 to 7, description previously given with reference to FIGS. 1 to 7 is briefly given or omitted.

The upper semiconductor package 200 may be precisely aligned on the lower semiconductor package 100 by using the alignment marks 128 to be stacked on the lower semiconductor package 100. Accordingly, a plurality of package connection terminals 204 may be directly connected to the plurality of external connection pads 65 of the redistribution structure 126.

The plurality of package connection terminals 204 may include, for example, solder balls or solder bumps. The plurality of package connection terminals 204 may electrically connect the lower semiconductor package 100 to the upper semiconductor package 200.

The upper semiconductor package 200 may include an upper semiconductor chip 212 attached onto an upper semiconductor package substrate 202. The upper semiconductor package substrate 202 may be electrically connected to the upper semiconductor chip 212 through bonding wires 214.

The upper semiconductor chip 212 may include, for example, a memory semiconductor chip. The memory semiconductor chip may include, for example, a volatile memory semiconductor chip such as dynamic random access memory (DRAM) or static random access memory (SRAM), or a non-volatile memory semiconductor chip such as phase-change random access memory (PRAM), magnetoresistive RAM (MRAM), ferroelectric RAM (FeRAM), or resistive RAM (RRAM).

The upper semiconductor chip 212 may include a plurality of semiconductor chips 206, 208, and 210. However, the disclosure is not limited thereto. For example, the upper semiconductor chip 212 may be a single chip. In some embodiments, the upper semiconductor package 200 may further include a controller chip for controlling the upper semiconductor chip 212.

The upper semiconductor package 200 may include a molding layer 216 surrounding the upper semiconductor chip 212. The molding layer 216 may include, for example, an EMC. Although the molding layer 216 is illustrated as covering a top surface of the upper semiconductor chip 212, the disclosure is not limited thereto.

As described above, the semiconductor package 300 may include a POP-type stacked semiconductor package in which the upper semiconductor package 200 electrically connected to the lower semiconductor package 100 through the plurality of package connection terminals 204 is attached onto the lower semiconductor package 100. In addition, in the POP type semiconductor package 300 according to the disclosure, the upper semiconductor package 200 may be precisely aligned on the lower semiconductor package 100 by using the alignment marks 128 to be stacked on the lower semiconductor package 100.

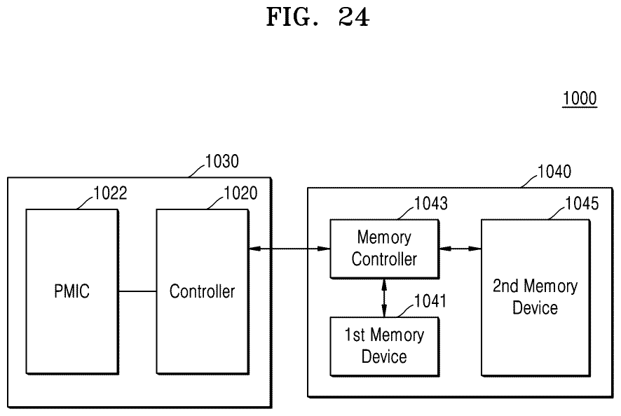

FIG. 24 is a block diagram illustrating a configuration of a semiconductor package 1000 according to an embodiment.

Specifically, the semiconductor package 1000 may include the semiconductor package 100, 100-1, 100-2, or 300 according to the disclosure. The semiconductor package 1000 may include a controller chip 1020, a first memory chip (or a first memory device) 1041, a second memory chip (or a second memory device) 1045, and a memory controller 1043.

The semiconductor package 1000 may further include a power management integrated circuit (PMIC) 1022 supplying currents of operating voltages to the controller chip 1020, the first memory chip 1041, the second memory chip 1045, and the memory controller 1043, respectively. The operating voltages respectively applied to the components may be designed to be the same or different from one another.

A lower semiconductor package 1030 including the controller chip 1020 and the PMIC 1022 may include the semiconductor package 100, 100-1, or 100-2 according to the disclosure. An upper semiconductor package 1040 including the first memory chip 1041, the second memory chip 1045, and the memory controller 1043 may include the upper semiconductor package 200 according to the disclosure.

The semiconductor package 1000 may be included in a personal computer (PC) or a mobile device. The mobile device may include a laptop computer, a mobile phone, a smartphone, a tablet PC, a personal digital assistant (PDA), an enterprise digital assistant (EDA), a digital still camera, a digital video camera, a portable multimedia player (PMP), a personal navigation device or portable navigation device (PND), a handheld game console, a mobile Internet device (MID), a wearable computer, an Internet of things (IoT) device, an Internet of everything (IoE) device, or a drone.

The controller chip 1020 may control operations of the first memory chip 1041, the second memory chip 1045, and the memory controller 1043. For example, the controller chip 1020 may include an integrated circuit (IC), a system on chip (SoC), an AP, a mobile AP, a chipset, or a set of chips. For example, the controller chip 1020 may include a CPU, a GPU, and/or a modem. In some embodiments, the controller chip 1020 may perform a function of the modem and a function of the AP.

The memory controller 1043 may control the second memory chip 1045 under control by the controller chip 1020. The first memory chip 1041 may include a volatile memory device. The volatile memory device may include RAM, DRAM, or SRAM. However, the disclosure is not limited thereto. The second memory chip 1045 may include a storage memory device. The storage memory device may include a non-volatile memory device. The non-volatile memory device may include a plurality of non-volatile memory cells.

The storage memory device may include a flash-based memory device. However, the disclosure is not limited thereto. The second memory chip 1045 may include a NAND-type flash memory device. The NAND-type flash memory device may include a two-dimensional (2D) memory cell array or a three-dimensional (3D) memory cell array. The 2D memory cell array or the 3D memory cell array may include a plurality of memory cells, and each of the plurality of memory cells may store 1-bit information or 2 or more-bit information.

When the second memory chip 1045 includes a flash-based memory device, the memory controller 1043 may use (or support) a multimedia card (MMC) interface, an embedded MMC (eMMC) interface, or a universal flash storage (UFS) interface. However, the disclosure is not limited thereto.

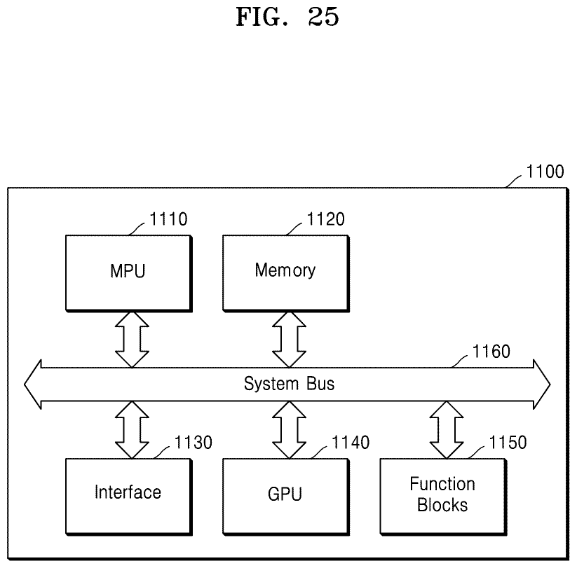

FIG. 25 is a block diagram schematically illustrating a configuration of a semiconductor package 1100 according to an embodiment.

Specifically, the semiconductor package 1100 may include an MPU 1110, memory 1120, an interface 1130, a GPU 1140, function blocks 1150, and a bus 1160 connecting the above components to one another. The semiconductor package 1100 may include both the MPU 1110 and the GPU 1140, or only one of the MPU 1110 and the GPU 1140.

The MPU 1110 may include a core and an L2 cache. For example, the MPU 1110 may include multiple cores. The multiple cores may have the same performance or different performances. In addition, the multiple cores may be simultaneously activated or may be activated at different points in time. The memory 1120 may store a result processed by the function blocks 1150 under control by the MPU 1110. For example, as content stored in the L2 cache of the MPU 1110 is flushed, the content may be stored in the memory 1120. The interface 1130 may interface with external devices. For example, the interface 1130 may interface with a camera, a liquid crystal display (LCD), and a speaker.

The GPU 1140 may perform graphics functions. For example, the GPU 1140 may process a video codec or may process 3D graphics. The function blocks 1150 may perform various functions. For example, when the semiconductor package 1100 is an AP used in a mobile device, some of the function blocks 1150 may perform a communication function.

The semiconductor package 1100 may include the semiconductor package 100, 100-1, 100-2, or 300 according to the disclosure. The MPU 1110 and/or the GPU 1140 may include the lower semiconductor package 100, 100-1, or 100-2 described above. The memory 1120 may include the upper semiconductor package 200 described above. The interface 1130 and the function blocks 1150 may correspond to a part of the lower semiconductor package 100, 100-1, or 100-2 described above.

While the disclosure has been particularly shown and described with reference to embodiments thereof, it will be understood that various changes in form and details may be made therein without departing from the spirit and scope of the following claims.

What is claimed is:

1. A semiconductor package comprising:
a base structure having a fan-in area and fan-out areas surrounding the fan-in area;
a semiconductor chip in the fan-in area;
a package body layer in the fan-in area and the fan-out areas, the package body layer covering the semiconductor chip;
a redistribution structure on the package body layer; and
alignment marks on the redistribution structure in a plan view,
wherein each of the alignment marks comprises a plurality of metal layers, and
wherein a plurality of auxiliary patterns are in the redistribution structure under the alignment marks to assist in recognition of the alignment marks.

2. The semiconductor package of claim 1, wherein the plurality of auxiliary patterns comprise a plurality of sub auxiliary patterns apart from one another in an X direction and a Y direction perpendicular to the X direction in the plan view.

3. The semiconductor package of claim 1, wherein the plurality of auxiliary patterns comprise a plurality of redistribution patterns in a transparent redistribution insulating layer in the plan view.

4. The semiconductor package of claim 1, wherein the base structure comprises a lower redistribution structure, and
wherein the redistribution structure comprises an upper redistribution structure.

5. The semiconductor package of claim 1, wherein the package body layer comprises a molding layer, and
wherein a metal post layer electrically connecting the base structure to the redistribution structure is in the package body layer.

6. The semiconductor package of claim 1, wherein each of the alignment marks comprises a triple metal layer or a double metal layer.

7. The semiconductor package of claim 1, wherein each of the alignment marks contacts the plurality of auxiliary patterns.

8. The semiconductor package of claim 1, wherein each of the alignment marks is in the redistribution structure.

9. The semiconductor package of claim 1, wherein each of the alignment marks is on the redistribution structure.

10. A semiconductor package comprising:
a lower redistribution structure having a fan-in area and fan-out areas surrounding the fan-in area;
a semiconductor chip in the fan-in area;
a package molding layer in the fan-in area and the fan-out areas, the package molding layer covering the semiconductor chip;
an upper redistribution structure on the package molding layer;
a metal post layer in the package molding layer, the metal post layer electrically connecting the lower redistribution structure to the upper redistribution structure; and
alignment marks on the upper redistribution structure in a plan view,
wherein each of the alignment marks comprises a plurality of metal layers, and
wherein a plurality of auxiliary patterns are in the upper redistribution structure under the alignment marks to assist in recognition of the alignment marks.

11. The semiconductor package of claim 10, wherein the upper redistribution structure comprises a transparent redistribution insulating layer, and
wherein the plurality of auxiliary patterns comprise a plurality of redistribution layers insulated from the transparent redistribution layer.

12. The semiconductor package of claim 10, wherein the plurality of auxiliary patterns comprise a plurality of sub auxiliary patterns apart from one another in an X direction and a Y direction perpendicular to the X direction in the plan view.

13. The semiconductor package of claim 10, wherein the plurality of auxiliary patterns comprise a plurality of redistribution layers at an uppermost part of the upper redistribution structure.

14. The semiconductor package of claim 10, wherein each of the alignment marks is in the upper redistribution structure and contacts a respective portion of the plurality of auxiliary patterns.

15. The semiconductor package of claim 10, wherein each of the alignment marks is on the upper redistribution structure separated from the upper redistribution structure by a redistribution insulating layer.

16. The semiconductor package of claim 10, wherein each of the alignment marks is on the upper redistribution structure in the plan view.

17. The semiconductor package of claim 10, wherein exposure holes exposing top surfaces of the plurality of auxiliary patterns are further formed around each of the alignment marks.

18. A semiconductor package comprising:
a lower semiconductor package;
an upper semiconductor package stacked on the lower semiconductor package, the upper semiconductor package having a size less than a size of the lower semiconductor package; and
a plurality of package connection terminals electrically connecting the lower semiconductor package to the upper semiconductor package, wherein the lower semiconductor package comprises:
a lower redistribution structure having a fan-in area and fan-out areas surrounding the fan-in area;
a semiconductor chip in the fan-in area;
a package molding layer in the fan-in area and the fan-out areas, the package molding layer covering the semiconductor chip;
an upper redistribution structure on the package molding layer;
a metal post layer in the package molding layer, the metal post layer electrically connecting the lower redistribution structure to the upper redistribution structure; and
alignment marks on the upper redistribution structure in a plan view,
wherein each of the alignment marks comprises a plurality of metal layers, and
wherein a plurality of auxiliary patterns are in the upper redistribution structure under the alignment marks to assist in recognition of the alignment marks.

19. The semiconductor package of claim 18, wherein a plurality of external connection pads connected to the plurality of package connection terminals are on the upper redistribution structure, and
wherein each of the alignment marks is at a same vertical level as a level of the plurality of external connection pads.

20. The semiconductor package of claim 18, wherein a plurality of external connection pads connected to the plurality of package connection terminals are on the upper redistribution structure, and
wherein each of the alignment marks is at a level lower than a level of the plurality of external connection pads, and
wherein each of the alignment marks contacts a respective portion of the plurality of auxiliary patterns.
